(19) United States
(12) Patent Application Publication
(10) Pub. No.: US 2022/0397244 A1
(43) Pub. Date: Dec. 15, 2022

(54) LED REFLECTOR DEVICE

(71) Applicant: Charles Suder, Fort Wayne, IN (US)

(72) Inventor: Charles Suder, Fort Wayne, IN (US)

(21) Appl. No.: 16/839,242

(22) Filed: Apr. 3, 2020

(51) Int. Cl. F21K 9/68; H05B 45/30; F21V 19/00; H01L 33/60

(52) U.S. Cl. CPC F21K 9/68; H05B 45/30; F21V 19/004; H01L 33/60

(57) ABSTRACT

A LED reflector device including a housing member, a light control member and a clip member. The housing member is formed by a front surface and a rear surface which are attached to one another creating an enclosure. The front surface includes a reflector lens for reflecting a plurality of light images generated from within the enclosure. The rear surface includes a board having a plurality of LED lights integrated therein for generating a plurality of light images within the enclosure. The light control member includes a mode control button for operating the plurality of LED lights in a first mode or a second mode. The clip member includes a clip mechanism for attaching the device to an object to improve the visibility in the area where the object is located.

### FIELD OF THE INVENTION

Embodiments described herein generally relate to reflector devices, and more particularly to LED reflector devices.

### BACKGROUND OF THE INVENTION

Though ski resorts usually have lights to allow better visibility throughout the trails after sundown, people who ski tend to have difficulty seeing clearly those around them and/or their immediate landscape. Parents who go skiing or snowboarding with their children may avoid doing so after sundown out of fear of not being able to maintain control of where their kids are, particularly for lack of visibility. Hence, an improved way to increase visibility throughout trails after sundown is desirable.

### BRIEF DESCRIPTION OF THE DRAWINGS

The various advantages of the embodiments of the present disclosure will become apparent to one skilled in the art by reading the following specification and appended claims, and by referencing the following drawing(s), in which:

FIG. 1 shows an exemplary rear perspective view of a LED reflector device according to an embodiment of the present disclosure.

FIG. 2 shows an exemplary front view of a LED reflector device according to an embodiment of the present disclosure.

FIG. 3 shows an exemplary rear view of a LED reflector device according to an embodiment of the present disclosure.

FIG. 4 shows an exemplary side view of a LED reflector device according to an embodiment of the present disclosure.

### SUMMARY OF THE INVENTION

Exemplary embodiments disclosed herein describe a LED reflector device including a housing member, a light control member and a clip member. The housing member is formed by a front surface and a rear surface which are attached to one another creating an enclosure. The front surface includes a reflector lens for reflecting a plurality of light images generated from within the enclosure. The rear surface includes a board having a plurality of LED lights integrated therein for generating a plurality of light images within the enclosure. The light control member includes a mode control button for operating the plurality of LED lights in a first mode or a second mode. The clip member includes a clip mechanism for attaching the device to an object to improve the visibility in the area where the object is located.

In some exemplary embodiments, in a first mode is a blinking mode.

In some exemplary embodiments, the second mode is a still mode.

In some exemplary embodiments, the housing member may be configured in different shapes and colors.

In some exemplary embodiments, the object is a ski helmet.

### DETAILED DESCRIPTION

The present disclosure relates to a light emitting diode (“LED”) reflector device (“the device”). The device provides improved visibility at a location where the visibility is poor after sundown, such as, for example, a ski trail. The device reflects light and may be attached to a person's helmet or to the back of a snowboard occupied by a person so that others are made aware of their presence. Particularly for caregivers, the device offers safety to children by allowing the caregivers to easily identify them after sundown. The device may be configured in different shapes, such as, for example, stars, hearts, rockets, turtles, etc., and the device may come in different colors.

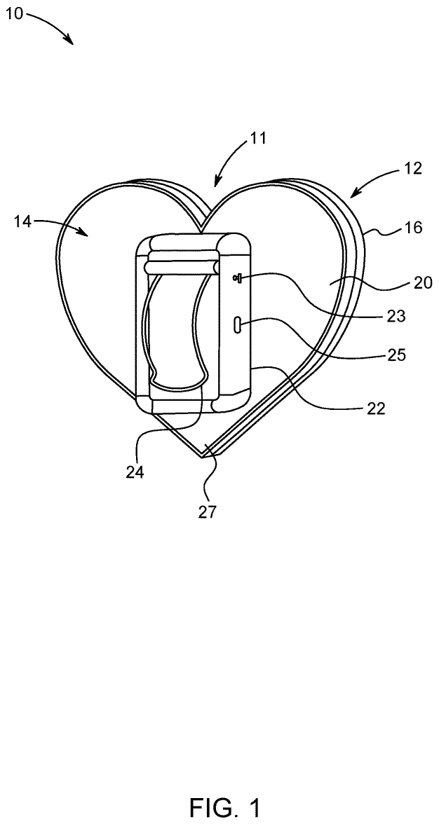

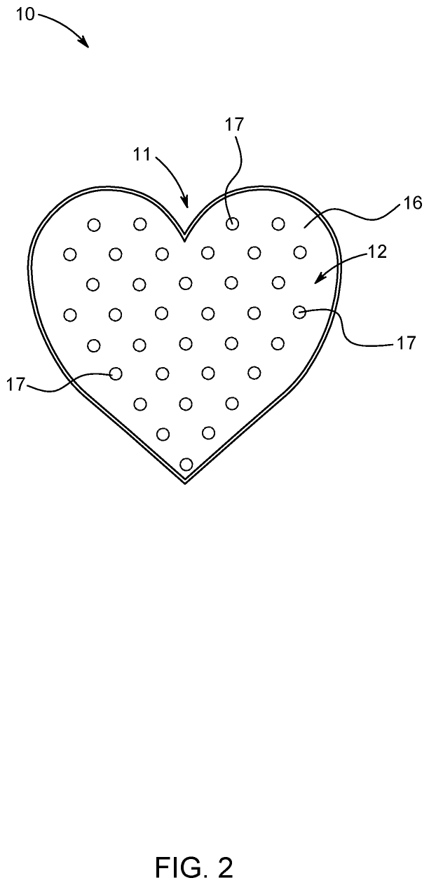

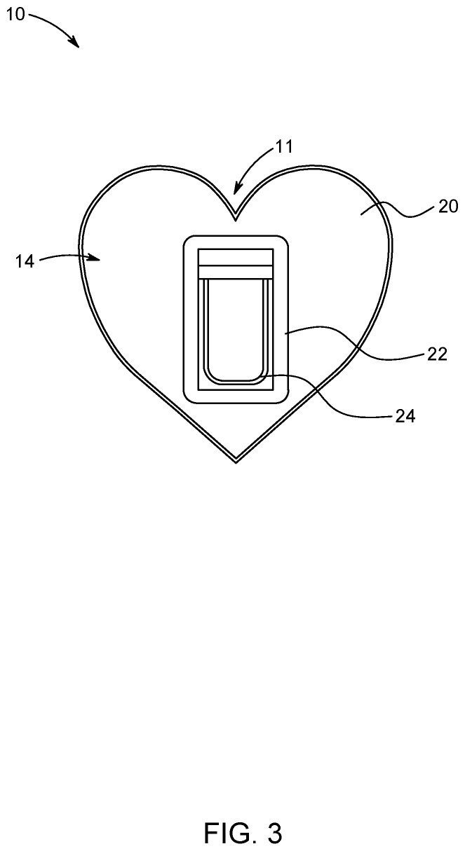

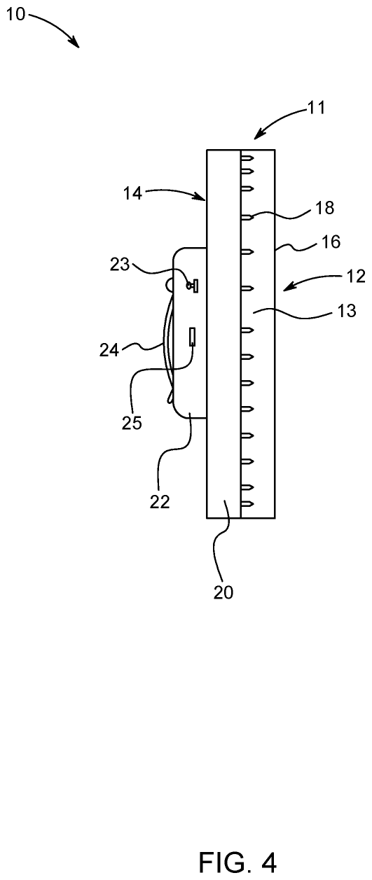

As illustrated in FIGS. 1-4, the device 10 includes a housing member 11, a light control member 22, and a clip member 24. The housing member is formed by a front surface 12 and a rear surface 14 which are attached to one another creating an enclosure 13. Although the exemplary figures show the housing member shaped as a heart, the housing member may be configured in any desired suitable shape, such as, for example, stars, hearts, moons, animals, planets, etc.

The front surface 14 includes a reflector lens 16 which reflects a plurality of light images 17 generated from a plurality of charged up LED lights 18 which are housed in the enclosure 13. The plurality of LED lights 18 are attached to an interior side of board 20 which is included on the rear surface 14. The board 20 may be any suitable board. However, in a preferred embodiment, the board 20 is a LED white board. In another exemplary embodiment, the device 10 includes a black plastic backing layer 27 on the rear surface directly behind board 20. Further, light control member 22 and clip member 24 are attached to the rear surface 14.

The light control member 22 includes a universal serial bus (USB) charging port 23 for charging an internal rechargeable battery. The rechargeable battery provides power to the LED lights. Moreover, the light control member has a mode control button 25 for operating the LED lights in a flashing (i.e., blinking) mode (i.e., first mode) or still mode (i.e., second mode). Moreover, the light control member includes an electrical circuit for causing the LED lights to blink when the flashing mode is activated. In a flashing mode, the LED lights continuously blink off and on. In a still mode, the LED lights are on continuously. The mode control button 25 may include a push button mechanism wherein when the push button is depressed the LED lights may operate in a first mode and when the push button is not pressed in the LED lights operate in a second mode.

The clip member 24 includes a clip mechanism for attaching the device 10 to another object, such as, for example, a helmet, or a snowboard, to improve the visibility in the area where the object is located. The reflected light from the device will illuminate the area where the attached object is located. Any suitable type of hardware clip mechanism may be used.

Moreover, it should be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.)

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

Those skilled in the art will appreciate from the foregoing description that the broad techniques of the embodiments of the present invention may be implemented in a variety of forms. Therefore, while the embodiments of this invention have been described in connection with particular examples thereof, the true scope of the embodiments of the invention should not be so limited since other modifications will become apparent to the skilled practitioner upon a study of the drawings, specification, and following claims.

1. A LED reflector device comprising:
a housing member formed by a front surface and a rear surface which are attached to one another creating an enclosure, the front surface including a reflector lens for reflecting a plurality of light images generated from within the enclosure, the rear surface including a LED white board having a plurality of LED lights integrated therein for generating a plurality of light images within the enclosure;
a light control member including a mode control button for operating the plurality of LED lights in a first mode or a second mode; and
a clip member including a clip mechanism for attaching the device to an object to improve the visibility in the area where the object is located.

2. The device of claim 1, wherein a first mode is a blinking mode.

3. The device of claim 1, wherein a second mode is a still mode.

4. The device of claim 1, wherein the housing member may be configured in different shapes and colors.

5. (canceled)
